(19) United States
(12) Patent Application Publication
(10) Pub. No.: US 2007/0102771 A1
(43) Pub. Date: May 10, 2007

(54) METAL OXIDE SEMICONDUCTOR DEVICE

(76) Inventor: Wen-Chieh Wang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,935

(22) Filed: Nov. 4, 2005

(51) Int. Cl. H01L 29/76

(52) U.S. Cl. 257/401

(57) ABSTRACT

The invention is directed to a gate conductive layer, wherein the gate conductive layer straddles over an isolation region and an active region in the isolation region. The gate conductive layer comprises a first portion and a second portion. The first portion is located over the active region and at least extending to a boundary between the isolation region and the active region. The second portion is located over the isolation region, wherein the second portion is connected to the first portion and the line width of the first portion is larger than that of the second portion.

### BACKGROUND OF THE INVENTION

1. Field of Invention

The present invention relates to a semiconductor device. More particularly, the present invention relates to a metal oxide semiconductor with a gate conductive layer.

2. Description of Related Art

When semiconductor process enters the deep sub-micron process generation, the size of the device is getting smaller and smaller. Therefore, it is a natural trend to manufacture more and more semiconductor devices at a finite wafer area to obtain a high integration of the semiconductor device. Furthermore, the size of the device is shrunk to full fill demands of the high operation speed and the low electric consumption.

However, once the size of the semiconductor device is decreased, it is necessary to change the layout of the semiconductor device. Therefore, the cost and the time for re-designing the layout are a lot. In order to save the cost for re-designing the layout, a shrink method is used to directly down size the original layout. That is, the whole device is shrunk so that number of devices formed on the same wafer can be increased to achieve the goals of the high operation speed and the low electric consumption.

However, when the whole device, such as a MOS transistor, is shrunk, the gate conductive layer within the MOS transistor is shrunk as well. Therefore, the electrical performance of the MOS transistor is affected. That is, the device made by directly shrinking the layout possesses the device characteristics different from the device properties of the device made by using the original layout. Therefore, the original layout still cannot be used in the next generation manufacturing process.

### SUMMARY OF THE INVENTION

Accordingly, at least one objective of the present invention is to provide a gate conductive layer capable of maintaining the electrical performance of the device by shrinking the size of the device without re-designing the layout.

At least another objective of the present invention is to provide a metal oxide semiconductor device capable of saving the cost for re-designing the layout by proportionally shrinking the size of the device.

To achieve these and other advantages and in accordance with the purpose of the invention, as embodied and broadly described herein, the invention provides a gate conductive layer, wherein the gate conductive layer straddles over an isolation region and an active region in the isolation region. The gate conductive layer comprises a first portion and a second portion. The first portion is located over the active region and at least extending to a boundary between the isolation region and the active region. The second portion is located over the isolation region, wherein the second portion is connected to the first portion and the line width of the first portion is larger than that of the second portion.

According to one embodiment of the present invention, the aforementioned first portion further comprises an extension portion located over the isolation region.

According to one embodiment of the present invention, a length of the aforementioned extension portion is no smaller than a minimum line width representing a resolution of a photolithography process and is smaller than a half of a space width between adjacent active regions.

According to one embodiment of the present invention, the aforementioned length of the extension portion is about 30 nm˜150 nm.

According to one embodiment of the present invention, a ratio of the line width of the aforementioned first portion to the line width of the aforementioned second portion is related to a shrink ratio of a circuit layout.

According to one embodiment of the present invention, the aforementioned ratio of the line width of the first portion to the line width of the second portion is the inverse of the shrink ratio.

According to one embodiment of the present invention, the line width of the aforementioned first portion is 1.01˜2 times of the line width of the aforementioned second portion.

According to one embodiment of the present invention, the aforementioned gate conductive layer is made of polysilicon.

According to one embodiment of the present invention, a metal silicide is located at a top portion of the aforementioned gate conductive layer over the active region.

The present invention also provides a metal oxide semiconductor device on an active region, wherein the active region is located in an isolation region. The metal oxide semiconductor device comprises a substrate, a gate dielectric layer and a gate conductive layer. The gate conductive layer is located on the gate dielectric layer, wherein the gate conductive layer straddles the active region and a portion of a conductive layer over the isolation region, the gate conductive layer possesses a first line width, the conductive layer which is located over the isolation region and are connected to the gate conductive layer possesses a second line width and the first line width is larger than the second line width.

According to one embodiment of the present invention, the aforementioned first portion further comprises an extension portion located over the isolation region.

According to one embodiment of the present invention, a length of the aforementioned extension portion is no smaller than a minimum line width representing a resolution of a photolithography process and is smaller than a half of a space width between adjacent active regions.

According to one embodiment of the present invention, the aforementioned length of the extension portion is about 30 nm˜150 nm.

According to one embodiment of the present invention, a ratio of the line width of the aforementioned first portion to the line width of the aforementioned second portion is related to a shrink ratio of a circuit layout.

According to one embodiment of the present invention, the aforementioned ratio of the line width of the first portion to the line width of the second portion is the inverse of the shrink ratio.

According to one embodiment of the present invention, the line width of the aforementioned first portion is 1.01˜2 times of the line width of the aforementioned second portion.

According to one embodiment of the present invention, the aforementioned gate conductive layer is made of polysilicon.

According to one embodiment of the present invention, a metal silicide is located at a top portion of the aforementioned gate conductive layer over the active region.

Since the line width of the gate conductive layer in the active region is increased, by proportionally shrinking the size of the original layout, the result device can still maintain the desirable electrical performance without re-designing the layout to full fill the demands of the new generation device. Therefore, the cost for re-designing the layout can be saved while the size of the device is decreased. Hence, on the same size of the wafer, the number of the devices formed on the wafer is increased. Thus, the goals of the high operation speed and low electric consumption can be achieved.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1C are schematic top views showing a gate conductive layer according to a preferred embodiment of the invention.

FIG. 2 is a cross-sectional view showing a metal oxide semiconductor device according to another embodiment of the present invention.

FIG. 3 is a top view of the metal oxide semiconductor device shown in FIG. 2.

### DESCRIPTION OF THE PREFERRED EMBODIMENTS

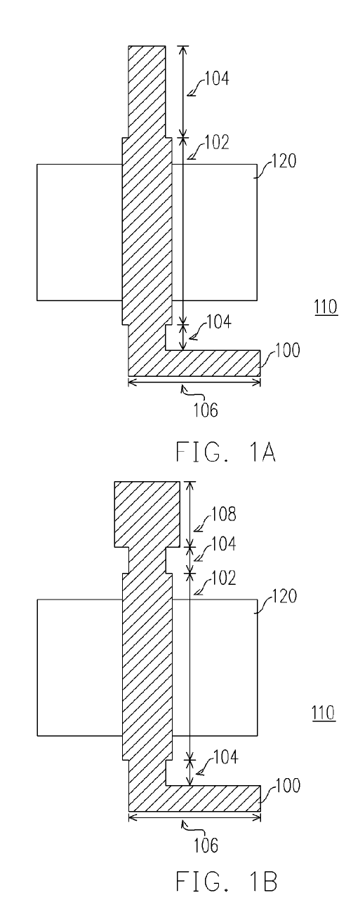

FIGS. 1A through 1C are schematic top views showing a gate conductive layer according to a preferred embodiment of the invention.

As shown in FIG. 1A, a gate conductive layer 100 straddles over an isolation region 110 and an active region 120 within the isolation region 110. The material of the gate conductive layer 100 includes polysilicon, doped polysilicon or other proper material. Furthermore, a metal silicide (not shown) is formed on the top of the gate conductive layer 100 over the active region 120. The metal silicide can be, for example but not limited to, tungsten silicide, nickel silicide or cobalt silicide. The gate conductive layer 100 comprises at least two portions. A first portion 102 of the gate conductive layer 100 is located in the active region 120 and extends to the boundary between the active region 120 and the isolation region 110. The first portion 102 further extends over the isolation region 110. A second portion 104 of the gate conductive layer 100 is located over the isolation region 110 and the second portion 104 and the first portion 102 are connected to each other. Furthermore, the line width of the first portion 102 is larger than that of the second portion 104.

The ratio of the line width of the first portion 102 to the line width of the second portion 104, that is the magnifying proportion of the first portion 102, is related to, for example but not limited to, a shrink ratio of the circuit layout. Preferably, the ratio of the line width of the first portion 102 to the line width of the second portion 104 is inverse of the shrink ratio. Moreover, the line width of the first portion 102 is 1.01˜2.00 times of the line width of the second portion 104.

It should be noticed that the method for magnifying the first portion 102 of the gate conductive layer 100 comprises step of magnifying the intersection region of the active region 120 and the gate conductive layer 100 by using Boolean operation. The magnifying operation can be, for example but not limited to, accomplished by extending the gate conductive layer 100 from the center thereof toward to both sides thereof with a bias value. That is, the gate conductive layer 100 is outwardly and equivalently magnified from the center thereof. Therefore, the extension portions of both side of the first portion 102 over the second portion 104 are equivalent. Taking the shrink ratio of 90% as an example, the circuit layout is shrunk to be 90% thereof so that it is necessary to magnify the first portion 102 of the gate conductive layer 100 to be 10/9 times of the original first portion 102 to maintain the electrical property as what before the circuit layout is shrunk. That is, the line width of the first portion 102 is 1.11 times of the line width of the second portion 104. On the other words, the line width of the first portion 102 is obtained by magnifying the line width of the original gate conductive layer 100 from the center towards to both sides of the gate conductive layer 100 for a magnifying amount of about 5%˜6%.

Moreover, the first portion 102 is not only located in the active region 120 but also extending to the isolation region 100. When the first portion 102 is magnified, because the line width of the first portion 102 is laterally and lengthwise magnified, the extension portion of the first portion 102 extends over the isolation region 110. The length of the extension portion of the first portion 102 is, for example, no smaller than the minimum line width representing the resolution of a photolithography process. Also, the length of the extension portion of the first portion 102 is smaller than a half of the space width between the adjacent active regions. For example, the space width between the active regions is about 300 nm so that the length of the extension portion of the first portion 102 should be less than 150 nm. That is, the length of the extension portion of the first portion 102 is about 30 nm˜150 nm. In one embodiment, the length of the extension portion of the first portion 102 can be, for example but not limited to, 100 nm.

Further, as shown in FIG. 1A, in one embodiment, the pattern of the gate conductive layer 100 not only straddles over the axial of the active region 120 but also extends towards to other directions. That gate conductive layer 100 further comprises a third portion 106. The third portion 106 is located on the isolation region 110 and connected to the second portion 104. The third portion 106 can be, for example but not limited to, located at an axial different from which the second portion 104 is located at. That is, the third portion 106 intersects the second portion 104 to form a corner. The third portion 106 of the gate conductive layer 100 can be, for example but not limited to, an extension portion extending over another active region (not shown) or being connected to a conductive line (not shown).

As shown in FIG. 1B, in another embodiment, the gate conductive layer 100 further comprises a fourth portion 108 located over the isolation region 110 and connected to the second portion 104. The line width of the fourth portion 108 can be, for example, larger than that of the second portion 104. The fourth portion 108 of the gate conductive layer 100 can be, for example but not limit to, a region on which a contact window is formed in the later performed process.

In the other embodiment, as shown in FIG. 1C, the line width of the fourth portion 108 of the gate conductive layer 100 can be, for example, smaller than that of the second portion 104. It should be noticed that the pattern and the width of the gate conductive layer 100 depend on the design of the device. Therefore, the present invention is not limited to by the above description.

Notably, in order to maintain the electrical property of the device after the circuit layout is shrunk, it is necessary to magnify the line width of the gate conductive layer. However, in the experiment, it is found that the process window of the gate conductive layer at the isolation region is relatively small. That is, the line width of the gate conductive layer over the isolation region is magnified so as to decrease the space width between two gate conductive layers. Hence, the bridge effect happens easily so that the short of the device happens and the yield is decreased. Accordingly, in order to maintain the electrical property and the yield of the product, the line width of the gate conductive layer is magnified and a portion of the magnified portion extends to cover the isolation region.

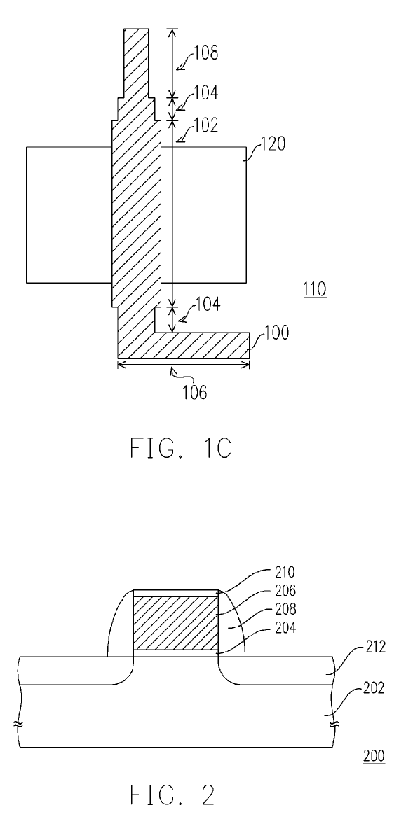

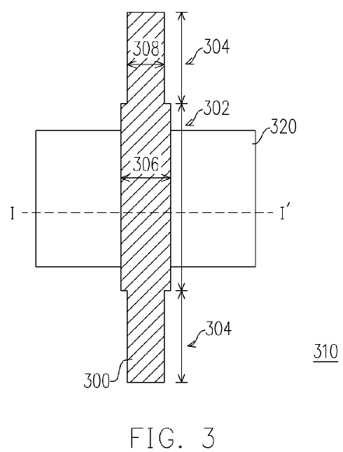

FIG. 2 is a cross-sectional view showing a metal oxide semiconductor device according to another embodiment of the present invention. FIG. 3 is a top view of the metal oxide semiconductor device shown in FIG. 2. FIG. 2 is the cross-sectional view of FIG. 3 along line I-I′.

As shown in FIG. 2 and FIG. 3, in the present embodiment, the metal oxide semiconductor device can be, for example, a metal oxide semiconductor device 200. The metal oxide semiconductor device 200 comprises a substrate 202, a gate dielectric layer 204, a gate 206 (as a gate conductive layer 302 shown in FIG. 3) and a source/drain region 212. The substrate 200 can be, for example but not limited to, a silicon substrate. The gate dielectric layer 204 is located on the substrate 202. The material of the gate dielectric layer 204 can be, for example but not limited to, silicon oxide. The gate 206 is located on the gate dielectric layer 204. The material of the gate 206 can be, for example but not limited to, polysilicon or doped polysilicon. There can be, for example but not limited to, a metal silicide layer 210 on the gate 206. The metal silicide layer 210 can be, for example, made of tungsten silicide, nickel silicide or cobalt silicide. The metal oxide semiconductor device 200 further comprises a spacer 208 located on the sidewall of the fate 206. The spacer 208 can be made of, for example but not limited to, silicon nitride. The source/drain region 212 is located in the substrate 202 adjacent to the gate 206. The source/drain region 212 can be, for example but not limited to, a doped region with either P type or N type dopants.

As shown in FIG. 3, gate conductive layer 302 (gate 206 shown in FIG. 2) can be, for example but not limited to, a part of a conductive layer 300. The conductive layer 300 can be, for example but not limited to, straddling over an isolation region 310 and an active region 320. The conductive layer 300 comprises a gate conductive layer 302 and a conductive layer 304, wherein the gate conductive layer 302 is located over the active region 320 and the conductive layer 304 is located over the isolation region 310 and connected to the gate conductive layer 302.

The line width 306 of the gate conductive layer 302 can be, for example, larger than the line width 308 of the conductive layer 304. The ratio of the line width 306 to the line width 308 is related to the shrink ratio of the circuit layout. That is, the ratio of the line width 306 to the line width 308 can be, for example, the inverse of the shrink ratio. For example, the line width 306 is 1.01˜2.00 times of the line width 308. Taking the shrink ratio of 90% as an example, the line width 306 should be magnified to be 10/9 times of the line width 308 to maintain the electrical property of the metal oxide semiconductor device.

Furthermore, as shown in FIG. 3, the gate conductive layer 302 can further extend to cover the isolation region 310. The length of the extension portion of the gate conductive layer 302 is no smaller than the minimum line width representing the resolution of the photolithography process. Also, the length of the extension portion of the gate conductive layer 302 is smaller than a half of the space width between the adjacent active regions. For example, the space width between the active regions is about 300 nm so that the length of the extension portion of the gate conductive layer 302 should be less than 150 nm. That is, the length of the extension portion of the gate conductive layer 302 is about 30 nm˜150 nm. In one embodiment, the length of the extension portion of the gate conductive layer 302 can be, for example but not limited to, 100 nm.

While the semiconductor process enters the next manufacture process generation, since the gate conductive layer possesses a relative large line width at the active region, the original circuit layout still can be utilized by being directly and proportionally shrunk without further re-designing the circuit layout. Even though the size of the device is decreased, the performance of the down sized devices is maintained. Therefore, the cost for re-designing the circuit layout can be saved. Further, because the size of the device is decreased, the number of the device on the same wafer is increased and the goals of the high operation speed and low electric consumption can be achieved.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A gate conductive layer, wherein the gate conductive layer straddles over an isolation region and an active region in the isolation region, comprising:
a first portion located over the active region and at least extending to a boundary between the isolation region and the active region; and
a second portion located over the isolation region, wherein the second portion is connected to the first portion and the line width of the first portion is larger than that of the second portion.

2. The gate conductive layer of claim 1, wherein the first portion further comprises an extension portion located over the isolation region.

3. The gate conductive layer of claim 2, wherein a length of the extension portion is no smaller than a minimum line width representing a resolution of a photolithography process and is smaller than a half of a space width between adjacent active regions.

4. The gate conductive layer of claim 2, wherein the length of the extension portion is about 30 nm˜150 nm.

5. The gate conductive layer of claim 1, wherein a ratio of the line width of the first portion to the line width of the second portion is related to a shrink ratio of a circuit layout.

6. The gate conductive layer of claim 5, wherein the ratio of the line width of the first portion to the line width of the second portion is the inverse of the shrink ratio.

7. The gate conductive layer of claim 1, wherein the line width of the first portion is 1.01˜2 times of the line width of the second portion.

8. The gate conductive layer of claim 1, wherein the gate conductive layer is made of polysilicon.

9. The gate conductive layer of claim 1, wherein a metal silicide is located at a top portion of the gate conductive layer over the active region.

10. A metal oxide semiconductor device on an active region, wherein the active region is located in an isolation region, the metal oxide semiconductor device comprising:
a substrate;
a gate dielectric layer; and
a gate conductive layer located on the gate dielectric layer, wherein the gate conductive layer straddles the active region and a portion of a conductive layer over the isolation region, the gate conductive layer possesses a first line width, the conductive layer which is located over the isolation region and are connected to the gate conductive layer possesses a second line width and the first line width is larger than the second line width.

11. The metal oxide semiconductor device of claim 10, wherein the gate conductive layer comprises an extension portion located over the isolation region.

12. The metal oxide semiconductor device of claim 11, wherein a length of the extension portion is no smaller than a minimum line width representing a resolution of a photolithography process and is smaller than a half of a space width between adjacent active regions.

13. The metal oxide semiconductor device of claim 11, wherein the length of the extension portion is about 30 nm˜150 nm.

14. The metal oxide semiconductor device of claim 10, wherein a ratio of the line width of the first portion to the line width of the second portion is related to a shrink ratio of a circuit layout.

15. The metal oxide semiconductor device of claim 14, wherein the ratio of the line width of the first portion to the line width of the second portion is the inverse of the shrink ratio.

16. The metal oxide semiconductor device of claim 10, wherein the line width of the first portion is 1.01˜2 times of the line width of the second portion.

17. The metal oxide semiconductor device of claim 10, wherein the gate conductive layer is made of polysilicon.

18. The metal oxide semiconductor device of claim 10, wherein a metal silicide is located at a top portion of the gate conductive layer over the active region.
